(19) United States
(12) Patent Application Publication
(10) Pub. No.: US 2009/0061611 A1
(43) Pub. Date: Mar. 5, 2009

(54) FABRICATING DUAL LAYER GATE ELECTRODES HAVING POLYSILICON AND A WORKFUNCTION METAL

(76) Inventors: Willy Rachmady, Beaverton, OR (US); Uday Shah, Portland, OR (US); Jack T. Kavalieros, Portland, OR (US); Brian S. Doyle, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/848,239

(22) Filed: Aug. 30, 2007

(51) Int. Cl. H01L 21/3205

(52) U.S. Cl. 438/592; 257/E21.295

(57) ABSTRACT

A method for fabricating a dual layer gate electrode having a polysilicon layer and a workfunction metal layer comprises depositing a layer of a workfunction metal on a semiconductor substrate, depositing a layer of polysilicon on the workfunction metal layer, depositing a hard mask layer on the polysilicon layer, etching the hard mask layer to form a hard mask structure defining a gate electrode, etching the polysilicon layer to remove a portion of the polysilicon layer not protected by the hard mask structure, thereby forming a polysilicon structure beneath the hard mask structure, applying a mixture of ozone and water to exposed sidewalls of the polysilicon structure, thereby forming a silicon dioxide layer on the sidewalls, and etching the workfunction metal layer to remove a portion of the workfunction metal layer not protected by the hard mask structure, thereby forming a workfunction metal structure beneath the polysilicon structure.

### BACKGROUND

In the manufacture of integrated circuit devices, planar and nonplanar transistors have dual-layer gate electrodes that are often formed using a combination of polysilicon and a workfunction metal. FIG. 1A illustrates a nonplanar tri-gate transistor 100 having such a gate electrode. As shown, the transistor 100 includes a silicon fin 102 serving as the transistor body. The fin 102 is electrically isolated by the isolation region 104, which is generally formed from a material such as silicon dioxide. A gate dielectric layer 106 is formed over the fin 102. Atop the gate dielectric layer 106 is a dual-layer gate electrode 108. In the tri-gate transistor 100, the gate electrode 108 is formed over three sides of the fin 102. As shown, the dual-layer gate electrode 108 includes a workfunction metal layer 108A and a polysilicon layer 108B.

The dual-layer gate electrode 108 is formed by first depositing a blanket layer of a workfunction metal and a blanket layer of polysilicon over the fin 102. Separate etch chemistries are then used to sequentially etch the polysilicon layer and the metal layer to form the gate electrode 108. Etching of the polysilicon layer occurs first, followed by etching of the metal layer. Unfortunately, conventional etch chemistries such as CF₄/Cl₂ used to etch the workfunction metal layer have low selectivity to polysilicon. As such, during the etch of the metal layer, portions of the already etched polysilicon layer are also removed. Unfortunately, there is an insufficient margin between achieving a complete etch of the workfunction metal and preserving the polysilicon. The result is a degraded polysilicon profile, as shown in the scanning electron microscope (SEM) images of FIG. 1B. Accordingly, improved methods of forming a polysilicon/workfunction metal gate electrode are needed.

### BRIEF DESCRIPTION OF THE DRAWINGS

FIG. 1A is a tri-gate transistor with a polysilicon/workfunction metal gate electrode.

FIG. 1B presents SEM images showing a degraded polysilicon profile that occurs when conventional methods are used to form a polysilicon/workfunction metal gate electrode.

FIG. 2 is a method of forming a gate electrode in accordance with implementations of the invention.

FIGS. 3A to 3D illustrate structures formed when the method of FIG. 2 is carried out.

FIG. 4 presents SEM images showing an improved polysilicon profile that occurs when methods of the invention are used to form polysilicon/workfunction metal gate electrodes.

### DETAILED DESCRIPTION

Described herein are systems and methods of forming a polysilicon and workfunction metal gate electrode with minimal polysilicon degradation. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

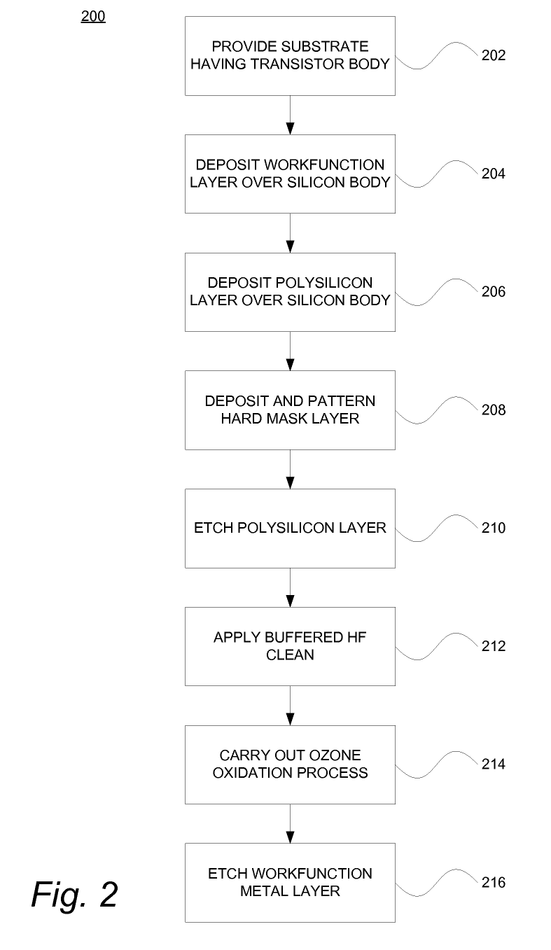

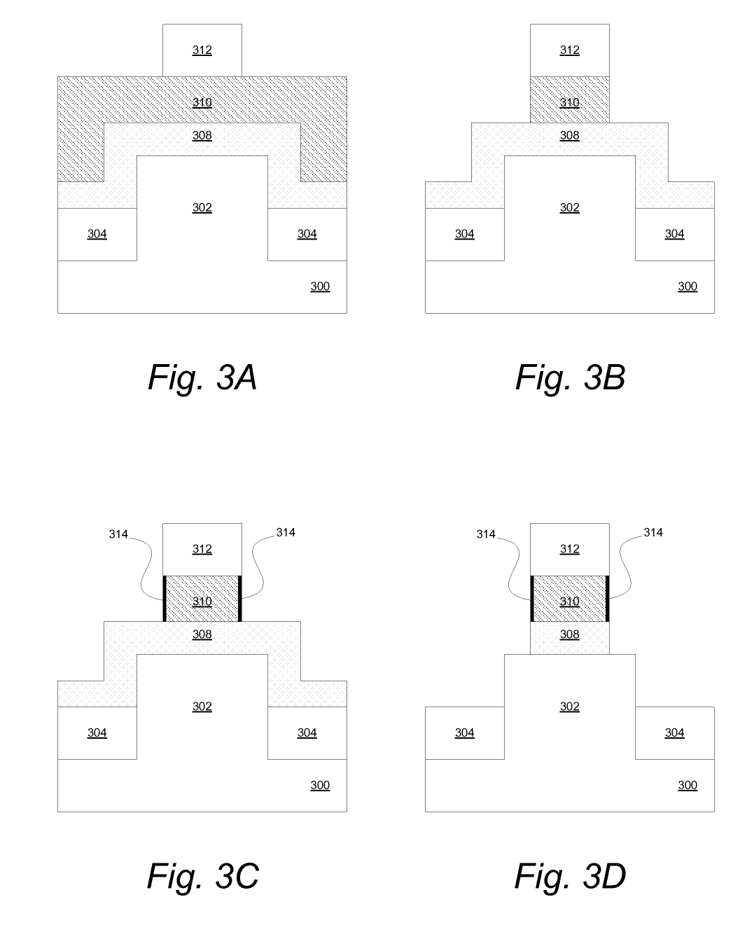

Implementations of the invention provide a process flow that uses a low temperature passivation technique to protect the polysilicon layer when the workfunction metal layer is being etched. FIG. 2 is a method 200 of forming a dual layer gate electrode in accordance with an implementation of the invention. FIGS. 3A to 3D illustrate structures that are formed when the method 200 of FIG. 2 is carried out.

The method 200 begins by providing a semiconductor substrate having a semiconductor body for use in a transistor (process 202 of FIG. 2). The semiconductor substrate is a crystalline substrate that may be formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

The semiconductor body may take one of several forms. For instance, if a planar transistor is being formed, the semiconductor body may simply consist of a region within the semiconductor substrate that will be used as a channel region for the transistor. On the other hand, if a non-planar transistor is being formed, the semiconductor body may consist of a silicon fin formed by patterning a portion of the semiconductor substrate. Methods of forming silicon fins are well known in the art and will not be described here.

A gate dielectric layer may be formed on the semiconductor body. The gate dielectric layer is known in the art and may be formed using materials that include, but are not limited to, silicon dioxide, carbon doped oxide, and high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Next, a blanket layer of a workfunction metal is deposited over the substrate (204). Conventional deposition processes may be used to deposit the metal layer, including but not limited to chemical vapor deposition (CVD) processes, atomic layer deposition (ALD) processes, physical vapor deposition (PVD) processes, sputtering, electroplating (EP) processes, and electroless plating (EL) processes. The specific workfunction metal used is chosen based on the needs and parameters of the transistor being formed, such as whether the transistor is a PMOS type transistor or an NMOS type transistor.

When the workfunction metal layer is used in an NMOS transistor, the metal preferably has a workfunction that is between about 3.9 eV and about 4.2 eV. N-type materials that may be used to form the workfunction metal layer include hafnium, zirconium, titanium, tantalum, aluminum, and metal carbides that include these elements, i.e., titanium carbide, zirconium carbide, tantalum carbide, hafnium carbide and aluminum carbide. When the workfunction metal layer is used in a PMOS transistor, the metal preferably has a workfunction that is between about 4.9 eV and about 5.2 eV. P-type materials that may be used to form the workfunction metal layer include ruthenium, palladium, platinum, cobalt, nickel, and conductive metal oxides, e.g., ruthenium oxide. The workfunction metal layer should be thick enough to ensure that any material formed on it will not significantly impact its workfunction. Depending on the type of metal used, the metal layer may be between about 15 angstroms (Å) and about 500 Å thick. Although a few examples of materials that may be used to form the metal layer are described here, other metals may also be used.

A blanket layer of polysilicon is deposited over the workfunction metal (206). Conventional methods of depositing polysilicon may be used, including but not limited to CVD, ALD, PVD, and epitaxial deposition. In implementations of the invention, the thickness of the polysilicon layer may range from around 100 Å to around 1500 Å.

A hard mask layer is deposited on the polysilicon layer and then patterned to form a hard mask structure (208). As will be recognized by those of skill in the art, the hard mask structure defines the gate electrode. The hard mask layer may be formed using conventional materials known in the art, including but not limited to silicon nitride (SiN). Known processes may be used to deposit and etch the hard mask material.

FIG. 3A illustrates a cross-section of a semiconductor substrate 300 that includes a semiconductor body 302 that may be used to form a non-planar transistor, such as a tri-gate transistor. The semiconductor body 302 is bordered by isolation regions 304 and has a gate dielectric layer (not shown for clarity) formed upon its surface. A blanket layer of a workfunction metal 308 is formed over the semiconductor body 302. A blanket layer of polysilicon 310 is formed over the workfunction metal layer 308. A patterned hard mask structure 312 is formed atop the polysilicon layer 310 and defines the gate electrode that will be formed.

The method 200 continues with an etching of the polysilicon layer (210). Conventional etch chemistries may be used to etch the polysilicon, for instance, an HBr/Cl₂ etch chemistry may be used. Etch chemistries comprising HBr, Cl₂, O₂, CF₄, and N₂ gases may also be used. The etching of the polysilicon continues down to the surface of the workfunction metal layer. The hard mask structure shields a portion of the polysilicon layer from the etching process. The masked polysilicon structure that remains after the etching is used to form the dual-layer gate electrode of the invention.

The polysilicon etch is followed by a buffered hydrofluoric (HF) acid clean chemistry (212). The HF clean removes etched polymer and prepares the exposed polysilicon surface (e.g., the exposed sidewalls of the polysilicon structure) for a subsequent chemical oxidation process.

FIG. 3B illustrates the structure after the polysilicon etch chemistry is applied. As shown, exposed portions of the polysilicon layer 310 not masked by the hard mask structure 312 are removed. The portion of the polysilicon layer 310 shielded by the hard mask structure 312 remains after etching, forming a polysilicon structure 310.

In accordance with implementations of the invention, an ozone oxidation process is carried out to oxidize and protect the exposed sidewalls of the polysilicon layer (214). Ozone is used during the oxidation process due to the superior tunneling characteristics that result in the transistor. Polysilicon readily reacts with ozone to form a high quality chemical oxide on the exposed surfaces of the polysilicon. The ozone (O₃) may be applied at a low temperature, such as room temperature, but the temperature may range from around 18° C. to around 70° C. In implementations of the invention, a mixture of ozone and water may be applied to carry out the ozone oxidation process. In one implementation, the ozone may be applied by spraying ozone-infused distilled water onto the substrate. In another implementation, the ozone may be applied by co-spraying ozone gas and distilled water onto the substrate.

In an implementation of the invention, ozone gas having a concentration between around 100 milligram per liter (mg/L) and around 300 mg/L in an N₂ carrier may be used for the oxidation process with an exposure that falls between around 30 seconds and around 120 seconds. These process conditions achieve a sufficient thickness of chemical oxide on the sidewalls of the polysilicon.

The ozone application causes a thin layer of silicon dioxide to form on the exposed sidewalls of the polysilicon structure. In implementations of the invention, this layer of silicon dioxide may have a thickness that ranges from around 5 Å to around 30 Å thick. The ozone oxidation chemistry is found to be very selective to the workfunction metal and minimally impacts the subsequent metal etch, thereby maintaining the metal workfunction and device integrity. FIG. 3C illustrates silicon dioxide layers 314 that have formed on the sidewalls of the polysilicon structure 310 during the ozone oxidation process.

After the polysilicon structure is protected by the silicon dioxide layers, a metal etch chemistry is applied to pattern the workfunction metal layer and form a workfunction metal structure below the polysilicon structure, thereby forming a dual-layer gate electrode (216). In implementations of the invention, a CF₄/Cl₂ metal etch chemistry may be used to remove portions of the metal layer not masked by the hard mask layer and the etched polysilicon layer. In accordance with implementations of the invention, the silicon dioxide formed on the sidewalls of the polysilicon layer preserve the polysilicon by minimizing or completely preventing exposure to the metal etch chemistry. As such, contrary to the prior art, the metal etch chemistry cannot adversely impact the polysilicon layer.

FIG. 3D illustrates a completed dual-layer gate electrode 316 formed after the patterning of the workfunction metal layer 308. As shown, the silicon dioxide layers 314 prevent the metal etch chemistry from contacting and etching the polysilicon structure 310. The end result is a dual-layer gate electrode 316 that has an intact polysilicon structure 310.

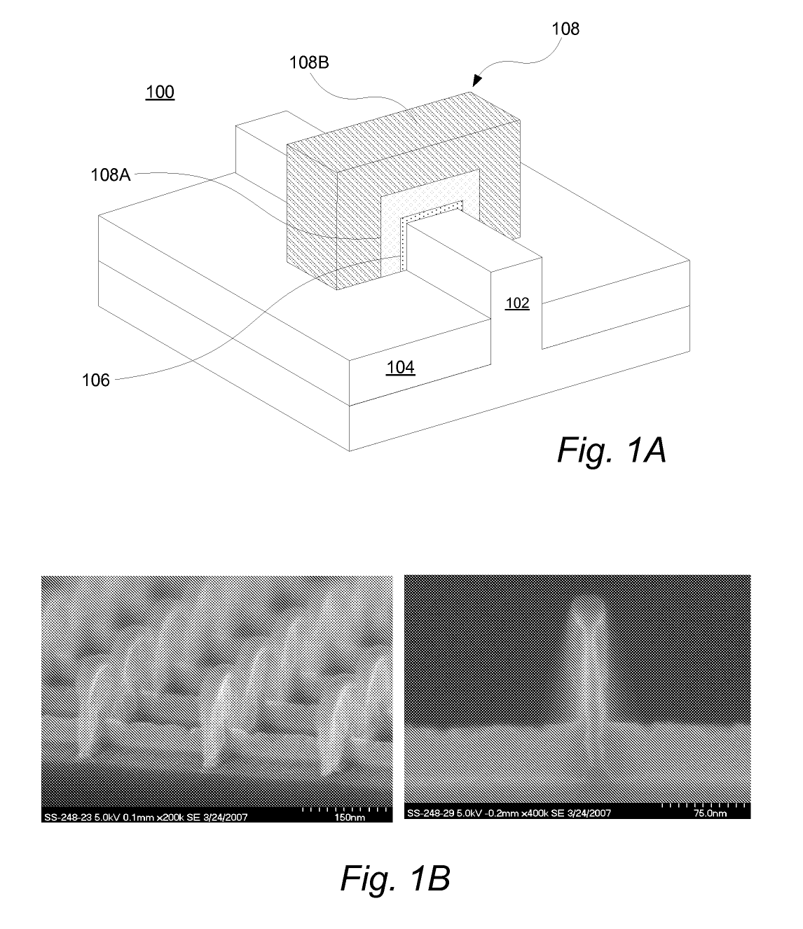

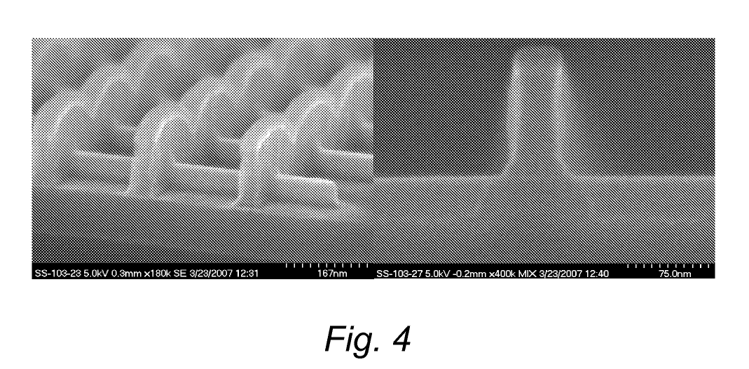

FIG. 4 presents two SEM images of dual-layer gate electrodes formed in accordance with implementations of the invention. Relative to the SEM images shown in FIG. 1B, the gate electrodes in FIG. 4 do not suffer from degraded polysilicon profiles. As shown, notching and flaring of the polysilicon is reduced or eliminated through the use of the ozone oxidation methods described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a semiconductor substrate;
depositing a blanket layer of a workfunction metal on the substrate;
depositing a blanket layer of polysilicon on the workfunction metal layer;
depositing a hard mask layer on the polysilicon layer;
etching the hard mask layer to form a hard mask structure defining a gate electrode;
etching the polysilicon layer to substantially remove a portion of the polysilicon layer not protected by the hard mask structure, thereby forming a polysilicon structure beneath the hard mask structure;
applying a mixture of ozone and water to exposed sidewalls of the polysilicon structure, thereby forming a silicon dioxide layer on the sidewalls; and
etching the workfunction metal layer to substantially remove a portion of the workfunction metal layer not protected by the hard mask structure, thereby forming a workfunction metal structure beneath the polysilicon structure.

2. The method of claim 1, wherein the semiconductor substrate includes a silicon fin formed on the substrate for use in a transistor.

3. The method of claim 1, wherein the semiconductor substrate includes a channel region formed within the substrate for use in a transistor.

4. The method of claim 1, wherein the workfunction metal is selected from the group consisting of hafnium, zirconium, titanium, tantalum, aluminum, metal carbides, titanium carbide, zirconium carbide, tantalum carbide, hafnium carbide, aluminum carbide, ruthenium, palladium, platinum, cobalt, nickel, conductive metal oxides, and ruthenium oxide.

5. The method of claim 1, wherein the workfunction metal layer has a thickness that falls between 15 Å and about 500 Å.

6. The method of claim 1, wherein the polysilicon layer has a thickness that falls between 100 Å and about 1500 Å.

7. The method of claim 1, further comprising applying a buffered HF clean chemistry after the etching of the polysilicon layer.

8. The method of claim 1, wherein the mixture of ozone and water is applied by spraying ozone-infused distilled water.

9. The method of claim 1, wherein the mixture of ozone and water is applied by co-spraying ozone gas and distilled water.

10. The method of claim 1, wherein the mixture of ozone and water is applied at a temperature that falls between 15° C. to around 70° C.

11. The method of claim 1, wherein the mixture of ozone and water has a concentration between around 100 mg/L and around 300 mg/L in an N₂ carrier.

12. The method of claim 1, wherein the sidewalls of the polysilicon structure are exposed to the mixture of ozone and water for between around 30 seconds and around 120 seconds.

13. The method of claim 1, wherein an HBr/Cl₂ etch chemistry is used to etch the polysilicon layer.

14. The method of claim 1, wherein a CF₄/Cl₂ metal etch chemistry is used to etch the workfunction metal layer.

15. A method comprising:
providing a semiconductor substrate having at least one silicon fin formed on its surface;
depositing a blanket layer of a workfunction metal over the silicon fin;
depositing a blanket layer of polysilicon on the workfunction metal layer;
depositing a hard mask layer on the polysilicon layer;
etching the hard mask layer to form a hard mask structure located above the silicon fin that defines a gate electrode;
etching the polysilicon layer to substantially remove portions of the polysilicon layer not protected by the hard mask structure, thereby forming a polysilicon structure above the silicon fin;
co-spraying ozone gas and distilled water to exposed sidewalls of the polysilicon structure, thereby forming silicon dioxide layers on the sidewalls; and
etching the workfunction metal layer to substantially remove a portion of the workfunction metal layer not protected by the hard mask structure, thereby forming a workfunction metal structure above the silicon fin.

16. The method of claim 15, wherein the ozone gas and distilled water are applied at a temperature that falls between 15° C. to around 70° C.

17. The method of claim 15, wherein the ozone gas has a concentration between around 100 mg/L and around 300 mg/L in an N₂ carrier.

18. The method of claim 15, wherein the etching of the polysilicon layer comprises applying an HBr/Cl₂ etch chemistry to the polysilicon.

19. The method of claim 15, wherein the co-spraying of the ozone gas and the distilled water continues until a layer of silicon dioxide is formed on the sidewalls having a thickness between around 5 Å and around 30 Å.

20. The method of claim 15, wherein the etching of the workfunction metal layer comprises applying a CF₄/Cl₂ metal etch chemistry to the workfunction metal layer.
